(19) United States
(12) Patent Application Publication
(10) Pub. No.: US 2015/0050792 A1
(43) Pub. Date: Feb. 19, 2015

(54) EXTRA NARROW DIFFUSION BREAK FOR 3D FINFET TECHNOLOGIES

(71) Applicant: GLOBALFOUNDRIES Inc., Grand Cayman (KY)

(72) Inventors: Srikanth B. Samavedam, Cohoes, NY (US); Zhenyu Hu, Clifton Park, NY (US); Andy Wei, Queensbury, NY (US); Qi Zhang, Mechanicville, NY (US); Nicholas V. LiCausi, Watervliet, NY (US); Daniel Pham, Clifton Park, NY (US)

(73) Assignee: GLOBALFOUNDRIES Inc., Grand Cayman (KY)

(21) Appl. No.: 13/965,258

(22) Filed: Aug. 13, 2013

(51) Int. Cl. H01L 29/06; H01L 21/762

(52) U.S. Cl. CPC H01L 29/0649; H01L 21/76224
USPC 438/296; 438/430

(57) ABSTRACT

Methods for forming a narrow isolation region are disclosed. The narrow isolation region may serve as an extra narrow diffusion break, suitable for use in 3D FinFET technologies. A pad nitride layer is formed over a semiconductor substrate. A cavity is formed in the pad nitride layer. A conformal spacer liner is deposited in the cavity. An anisotropic etch process then forms a trench in the semiconductor substrate. The trench is narrow enough such that a dummy gate completely covers the trench. Epitaxial stressor regions may then be formed adjacent to the dummy gate. The trench is narrow enough such that there is a gap between the epitaxial stressor regions and the trench.

### FIELD OF THE INVENTION

The present invention relates generally to semiconductors, and more particularly to formation of isolation regions.

### BACKGROUND

In modern semiconductor device applications, numerous devices are packed onto a single small area of a semiconductor substrate to create an integrated circuit. For the circuit to function, many of these individual devices may need to be electrically isolated from one another. Accordingly, electrical isolation is an important and integral part of semiconductor device design for preventing the unwanted electrical coupling between adjacent components and devices.

As the size of integrated circuits is reduced, the devices that make up the circuits must be positioned closer together in order to comply with the limited space available on a typical semiconductor substrate. As the industry strives towards a greater density of active components per unit area of semiconductor substrate, effective isolation between circuits becomes increasingly important.

### SUMMARY OF THE INVENTION

In a first aspect, embodiments of the present invention provide a method of forming a semiconductor structure, comprising: forming a pad oxide layer on a semiconductor substrate; forming a pad nitride layer on the pad oxide layer; performing a first etch to form a pad nitride layer cavity; depositing a conformal spacer film in the pad nitride layer cavity; and performing a second etch to open the conformal spacer film and forming a trench cavity in the semiconductor substrate.

In a second aspect, embodiments of the present invention provide a method of forming a semiconductor structure, comprising: forming a pad oxide layer on a semiconductor substrate; forming a pad nitride layer on the pad oxide layer; performing a first etch to form a pad nitride layer cavity; depositing a conformal spacer film in the pad nitride layer cavity; performing a second etch to open the conformal spacer film and forming a trench cavity in the semiconductor substrate; depositing an oxide layer to fill the trench cavity; and forming a gate on the trench cavity.

In a third aspect, embodiments of the present invention provide a method of forming a semiconductor structure, comprising: forming a pad oxide layer on a semiconductor substrate; forming a pad nitride layer on the pad oxide layer; performing a first etch to form a pad nitride layer cavity; depositing a conformal nitride liner in the pad nitride layer cavity; performing a second etch to open the conformal nitride liner and form a trench cavity in the semiconductor substrate; depositing an oxide layer to fill the trench cavity; and forming a dummy gate on the trench cavity.

### BRIEF DESCRIPTION OF THE DRAWINGS

Certain elements in some of the figures may be omitted, or illustrated not-to-scale, for illustrative clarity. The cross-sectional views may be in the form of “slices”, or “near-sighted” cross-sectional views, omitting certain background lines which would otherwise be visible in a “true” cross-sectional view, for illustrative clarity.

Often, similar elements may be referred to by similar numbers in various figures of the drawing, in which case typically the last two significant digits may be the same, the most significant digit being the number of the drawing figure. Furthermore, for clarity, some reference numbers may be omitted in certain drawings.

Features of this invention will be more readily understood from the following detailed description of the various aspects of the invention taken in conjunction with the accompanying drawings in which:

FIG. 1 is a semiconductor structure at a starting point for illustrative embodiments;

FIG. 2 is a semiconductor structure after a subsequent process step of forming a pad nitride layer cavity for illustrative embodiments;

FIG. 3 is a semiconductor structure after a subsequent process step of depositing a conformal spacer film in the pad nitride layer cavity for illustrative embodiments;

FIG. 4 is a semiconductor structure after a subsequent process step of forming a trench cavity in the semiconductor substrate for illustrative embodiments;

FIG. 5 is a semiconductor structure after a subsequent process step of depositing an oxide layer to fill the trench cavity for illustrative embodiments;

FIG. 6 is a semiconductor structure after a subsequent process step of planarizing the oxide layer for illustrative embodiments;

FIG. 7 is a semiconductor structure after a subsequent process step of forming a gate on the trench cavity for illustrative embodiments; and

FIG. 8 is a flowchart indicating process steps for illustrative embodiments.

### DETAILED DESCRIPTION

Embodiments of the present invention provide methods for forming a narrow isolation region. The narrow isolation region may serve as an extra narrow diffusion break, suitable for use in 3D FinFET technologies. A pad nitride layer is formed over a semiconductor substrate. A cavity is formed in the pad nitride layer. A conformal spacer liner is deposited in the cavity. An anisotropic etch process then forms a trench in the semiconductor substrate. The trench is narrow enough such that a dummy gate completely covers the trench. Epitaxial stressor regions may then be formed adjacent to the dummy gate. The trench is narrow enough such that there is a gap between the epitaxial stressor regions and the trench.

It will be appreciated that this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. The terminology used herein is for the purpose of describing particular embodiments only and is not intended to be limiting of this disclosure. For example, as used herein, the singular forms “a”, “an”, and “the” are intended to include the plural forms as well, unless the context clearly indicates otherwise. Furthermore, the use of the terms “a”, “an”, etc., do not denote a limitation of quantity, but rather denote the presence of at least one of the referenced items. It will be further understood that the terms “comprises” and/or “comprising”, or “includes” and/or “including”, when used in this specification, specify the presence of stated features, regions, integers, steps, operations, elements, and/or components, but do not preclude the presence or addition of one or more other features, regions, integers, steps, operations, elements, components, and/or groups thereof.

Reference throughout this specification to “one embodiment,” “an embodiment,” “embodiments,” “exemplary embodiments,” or similar language means that a particular feature, structure, or characteristic described in connection with the embodiment is included in at least one embodiment of the present invention. Thus, appearances of the phrases “in one embodiment,” “in an embodiment,” “in embodiments” and similar language throughout this specification may, but do not necessarily, all refer to the same embodiment.

The terms “overlying” or “atop”, “positioned on” or “positioned atop”, “underlying”, “beneath” or “below” mean that a first element, such as a first structure (e.g., a first layer), is present on a second element, such as a second structure (e.g. a second layer), wherein intervening elements, such as an interface structure (e.g. interface layer), may be present between the first element and the second element.

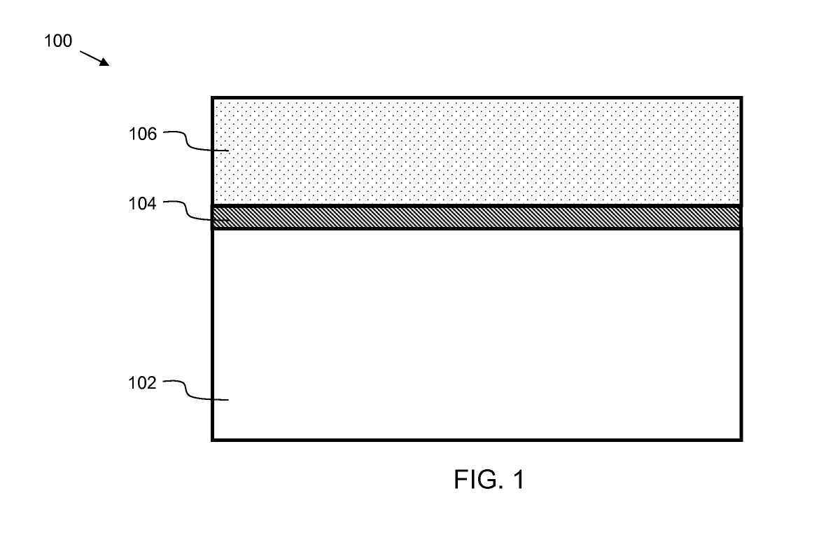

FIG. 1 is a semiconductor structure 100 at a starting point for illustrative embodiments. A semiconductor substrate 102, which may include a silicon substrate, such as a bulk silicon substrate, forms the base of semiconductor structure 100. A pad oxide layer 104, such as a silicon oxide layer, is disposed on semiconductor substrate 102. In embodiments, the pad oxide layer 104 may have a thickness raging from about 1 nanometer to about 10 nanometers. A pad nitride layer 106, such as a silicon nitride layer, is disposed on pad oxide layer 104. In embodiments, the pad nitride layer 106 may have a thickness ranging from about 20 nanometers to about 60 nanometers.

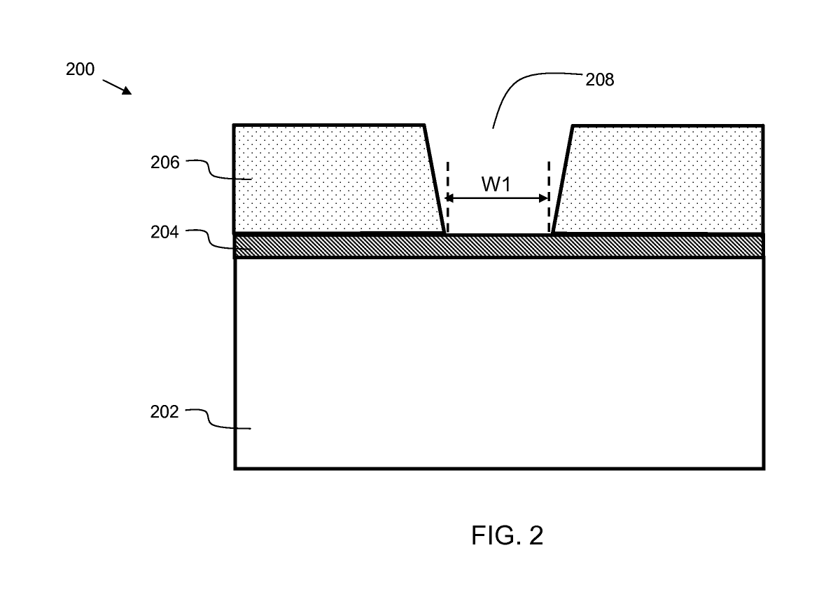

FIG. 2 is a semiconductor structure 200 after a subsequent process step of forming a pad nitride layer cavity 208 in the pad nitride layer 206. As stated previously, similar elements may be referred to by similar numbers in various figures (FIGs) of the drawing, in which case typically the last two significant digits may be the same. For example, semiconductor substrate 202 of FIG. 2 is similar to semiconductor substrate 102 of FIG. 1.

The pad nitride layer cavity 208 is formed via an anisotropic etch. In embodiments, a reactive ion etch (RIE) process is used to form the pad nitride layer cavity. The pad nitride layer cavity 208 has a lower width W1. In embodiments, lower width W1 may range from about 35 nanometers to about 55 nanometers. The minimum value of lower width W1 is limited by the lithographic technology used. However, in order to form an extra narrow substrate trench, it is desirable to reduce the effective lower width of the pad nitride layer cavity 208 to a value even less than W1, as further detailed in the following steps.

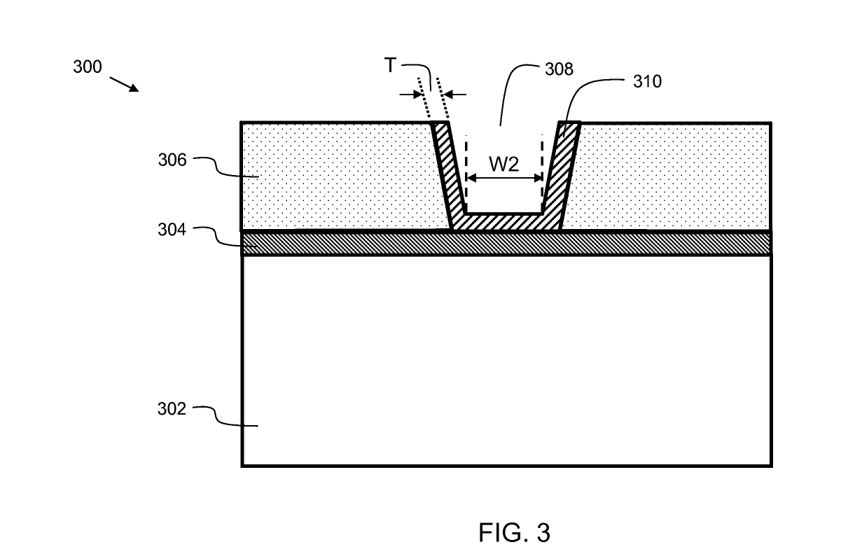

FIG. 3 is a semiconductor structure 300 after a subsequent process step of depositing a conformal spacer film 310 in the pad nitride layer cavity 308. In embodiments, the conformal spacer film 310 has a thickness T ranging from about 5 nanometers to about 15 nanometers. In particular embodiments, the conformal spacer film 310 has a thickness T of about 10 nanometers. In embodiments, the conformal spacer film 310 may be made from a nitride, such as a silicon nitride, and may be deposited via chemical vapor deposition (CVD), or low pressure chemical vapor deposition (LPCVD). In embodiments where the conformal spacer film 310 is comprised of nitride, it may be referred to as a “conformal nitride liner.” The effective lower width W2 of the pad nitride layer cavity 308 is now reduced by approximately two times the thickness T of conformal spacer film 310. In an example, if W1 (FIG. 2) is about 55 nanometers, and thickness T of conformal spacer film 310 is 10 nanometers, then effective lower width W2 is approximately given by:

W1−2T=55−2(10)=35 nanometers.

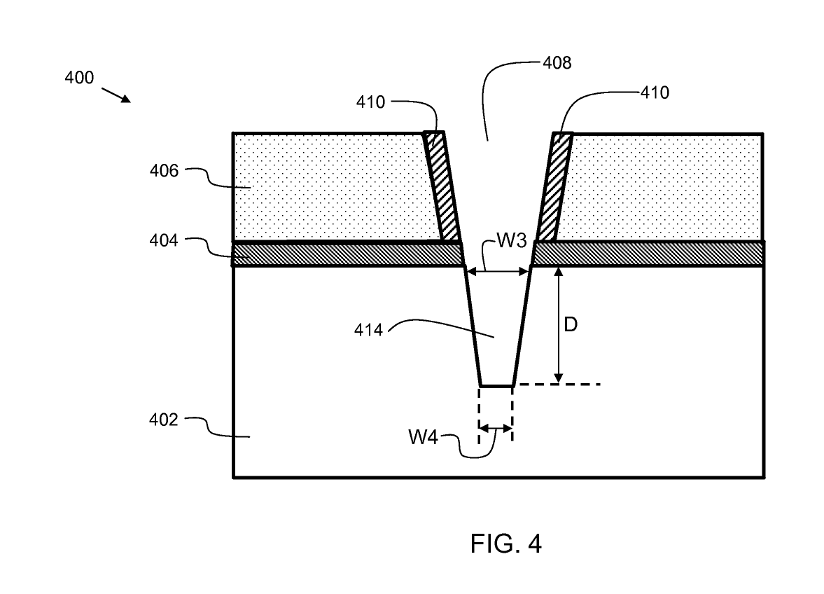

FIG. 4 is a semiconductor structure 400 after a subsequent process step of forming a trench cavity 414 in the semiconductor substrate 402. The bottom portion of the conformal spacer liner is removed, leaving inner spacers 410 in the pad nitride layer cavity 408. Trench cavity 414 has an upper width W3 and a lower width W4. In some embodiments, trench cavity 414 has an upper width W3 ranging from about 15 nanometers to about 35 nanometers, and has a lower width W4 ranging from about 5 nanometers to about 15 nanometers. In other embodiments, trench cavity 414 has an upper width W3 ranging from about 28 nanometers to about 32 nanometers, and has a lower width W4 ranging from about 9 nanometers to about 11 nanometers. In some embodiments, the trench cavity has a depth D ranging from about 100 nanometers to about 140 nanometers. In other embodiments, the trench cavity 414 has a depth D ranging from about 80 nanometers to about 110 nanometers. Reducing the width W3 beyond the lithographic capabilities that form pad nitride layer cavity 208 (having width W1) is important. A key reason is that during subsequent processing steps, a dummy gate may be formed over the trench cavity 414, and it is important for the trench cavity upper width to be less than the width of the dummy gate in order to facilitate proper epitaxial growth of stressor regions.

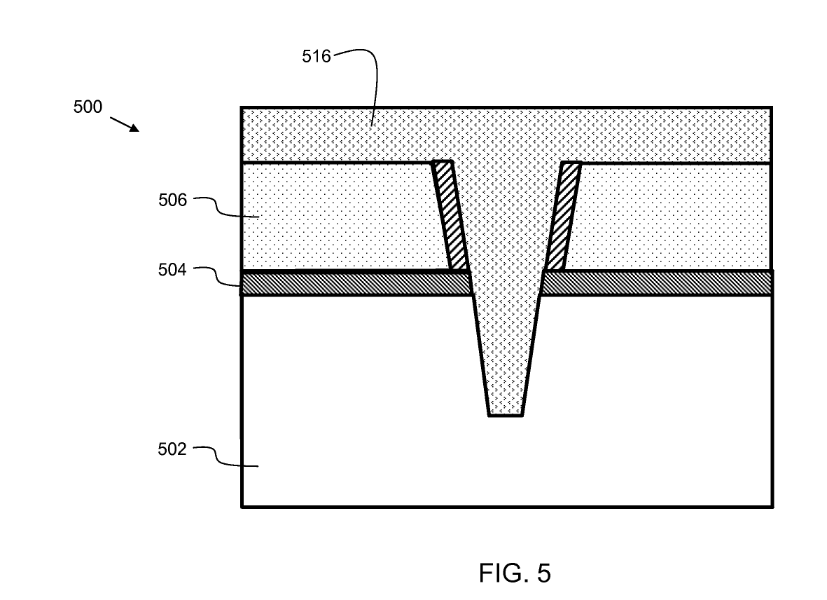

FIG. 5 is a semiconductor structure 500 after a subsequent process step of depositing an oxide layer 516 to fill the trench cavity. In embodiments, oxide layer 516 is comprised of silicon oxide. Oxide layer 516 may be a HARP (High Aspect Ratio Process) oxide. Preferably, the oxide layer 516 should have good gap fill properties to completely fill the trench cavity without forming any large voids in the trench cavity.

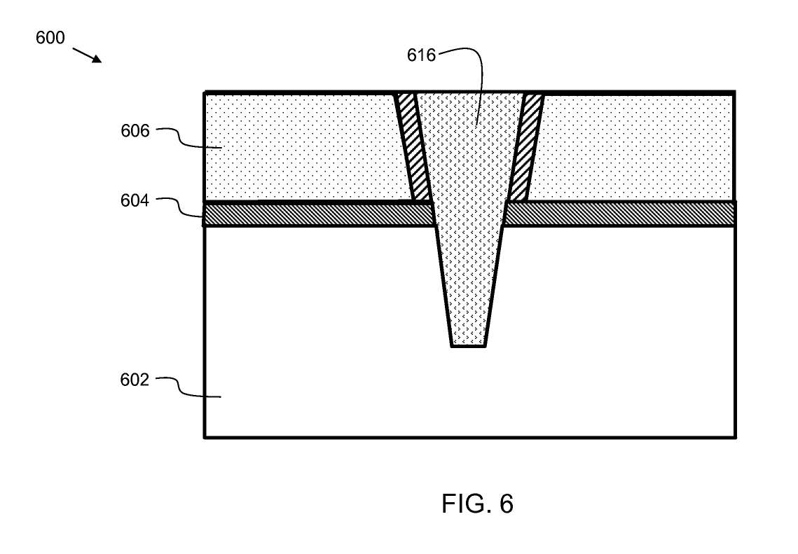

FIG. 6 is a semiconductor structure 600 after a subsequent process step of planarizing the oxide layer 616. In embodiments, the planarization may be performed via a chemical mechanical polish (CMP) process. The planarization process may stop on the pad nitride layer 606.

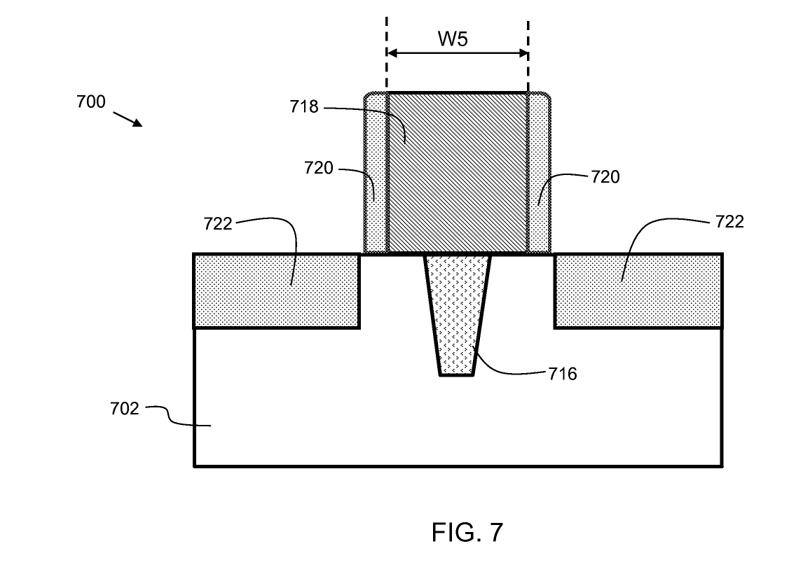

FIG. 7 is a semiconductor structure 700 after subsequent process steps of additional recess and/or planarization and forming a gate 718 on the trench cavity for illustrative embodiments. Spacers 720 may be formed adjacent to gate 718. Prior to forming gate 718, and additional recess and/or planarization may be performed to remove the pad nitride and pad oxide layers (see 104 and 106 of FIG. 1). Gate 718 may be a “dummy” gate that is not electrically active, and is used for the purposes of serving as a masking feature to allow formation of stressor regions 722. Stressor regions 722 may be formed by etching or recessing substrate 702, followed by growing an epitaxial stressor region 722. Stressor region 722 may include, but is not limited to, silicon carbon (SiC), silicon germanium (SiGe), and silicon carbon phosphorous (SiCP) materials. While the stressor regions 722 are shown as rectangular, other shapes are possible, such as a sigma cavity shape. The epitaxial regions 722 will not form properly if in contact with filled trench cavity 716. Hence, as stated previously, it is important for the trench cavity upper width (W3 of FIG. 4) to be less than the width W5 of the gate 718 in order to facilitate proper epitaxial growth of stressor regions 722.

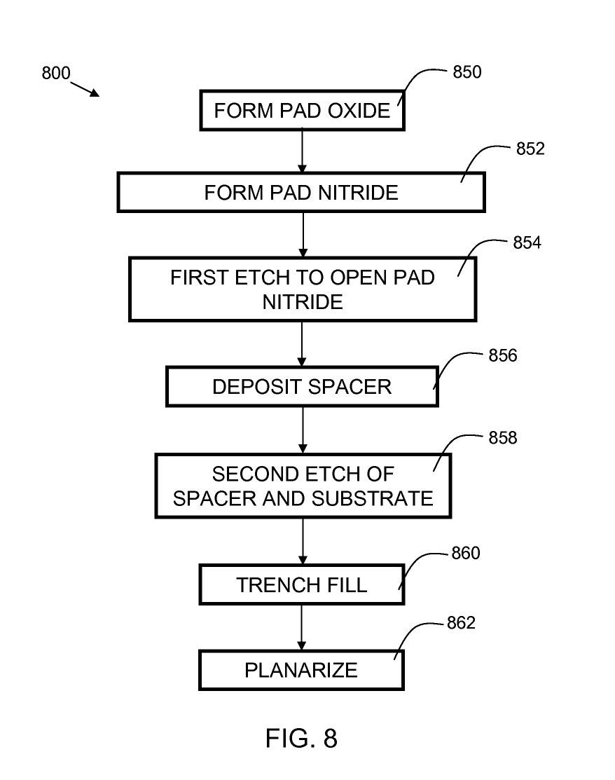

FIG. 8 is a flowchart 800 indicating process steps for illustrative embodiments. In process step 850, a pad oxide is formed on the semiconductor substrate (see 104 of FIG. 1). In process step 852, a pad nitride is formed on the pad oxide (see 106 of FIG. 1). In process step 854, a first etch is performed to open the pad nitride and form a pad nitride cavity (see 208 of FIG. 2). In process step 856, a conformal spacer layer is deposited on the sidewalls and bottom of the pad nitride cavity (see 310 of FIG. 3). In process step 858, a second etch is performed to remove the bottom portion of the conformal spacer layer and etch a trench in the semiconductor substrate (see 400 of FIG. 4). In process step 860, the trench is filled with an oxide material (see 516 of FIG. 5). In process step 862, the semiconductor structure is planarized (see 600 of FIG. 6). From this point forward, techniques known in the industry may be used to complete fabrication of the semiconductor structure. This may include forming of dummy gates via a sidewall image transfer (SIT) process or other suitable process, as well as providing additional dielectric layers, metallization layers, and packaging. This process can be used in conjunction with a gate first or replacement metal gate scheme.

While the invention has been particularly shown and described in conjunction with exemplary embodiments, it will be appreciated that variations and modifications will occur to those skilled in the art. For example, although the illustrative embodiments are described herein as a series of acts or events, it will be appreciated that the present invention is not limited by the illustrated ordering of such acts or events unless specifically stated. Some acts may occur in different orders and/or concurrently with other acts or events apart from those illustrated and/or described herein, in accordance with the invention. In addition, not all illustrated steps may be required to implement a methodology in accordance with the present invention. Furthermore, the methods according to the present invention may be implemented in association with the formation and/or processing of structures illustrated and described herein as well as in association with other structures not illustrated. Therefore, it is to be understood that the appended claims are intended to cover all such modifications and changes that fall within the true spirit of the invention.

1. A method of forming a semiconductor structure, comprising:
forming a pad oxide layer on a semiconductor substrate;
forming a pad nitride layer on the pad oxide layer;
performing a first etch to form a pad nitride layer cavity selective to a top surface of the pad oxide layer;
depositing a conformal spacer film in the pad nitride layer cavity, wherein the conformal spacer film is deposited along the top surface of the pad oxide layer; and
performing a second etch to open the conformal spacer film and forming a trench cavity in the semiconductor substrate.

2. The method of claim 1, wherein depositing a conformal spacer film comprises depositing a nitride liner.

3. The method of claim 1, further comprising depositing an oxide layer to fill the trench cavity.

4. The method of claim 3, further comprising planarizing the oxide layer.

5. The method of claim 4, wherein planarizing the oxide layer is performed via a chemical mechanical polish process.

6. The method of claim 2, wherein depositing a nitride liner comprises depositing a nitride liner having a thickness ranging from about 5 nanometers to about 15 nanometers.

7. The method of claim 1, wherein forming a pad nitride layer cavity comprises forming a cavity with a lower width ranging from about 45 nanometers to about 55 nanometers.

8. The method of claim 7, wherein forming a trench cavity in the semiconductor substrate comprises forming a trench cavity having a depth ranging from about 100 nanometers to about 140 nanometers.

9. The method of claim 8, wherein forming a trench cavity in the semiconductor substrate comprises forming a trench cavity having an upper width ranging from about 25 nanometers to about 35 nanometers, and wherein the trench cavity has a lower width ranging from about 5 nanometers to about 15 nanometers.

10. A method of forming a semiconductor structure, comprising:
forming a pad oxide layer on a semiconductor substrate;
forming a pad nitride layer on the pad oxide layer;
performing a first etch to form a pad nitride layer cavity selective to a top surface of the pad oxide layer;
depositing a conformal spacer film in the pad nitride layer cavity, wherein the conformal spacer film is deposited along the top surface of the pad oxide layer;
performing a second etch to open the conformal spacer film and forming a trench cavity in the semiconductor substrate;
depositing an oxide layer to fill the trench cavity; and
forming a gate on the trench cavity.

11. The method of claim 10, further comprising planarizing the oxide layer.

12. The method of claim 11, wherein planarizing the oxide layer is performed via a chemical mechanical polish process.

13. The method of claim 10, wherein depositing a conformal spacer film comprises depositing a conformal spacer film having a thickness ranging from about 5 nanometers to about 15 nanometers.

14. The method of claim 10, wherein forming a pad nitride layer cavity comprises forming a cavity with a lower width ranging from about 35 nanometers to about 55 nanometers.

15. The method of claim 14, wherein forming a trench cavity in the semiconductor substrate comprises forming a trench cavity having a depth ranging from about 100 nanometers to about 140 nanometers.

16. The method of claim 15, wherein forming a trench cavity in the semiconductor substrate comprises forming a trench cavity having an upper width ranging from about 25 nanometers to about 35 nanometers, and wherein the trench cavity has a lower width ranging from about 5 nanometers to about 15 nanometers.

17. A method of forming a semiconductor structure, comprising:
forming a pad oxide layer on a semiconductor substrate;
forming a pad nitride layer on the pad oxide layer;
performing a first etch to form a pad nitride layer cavity selective to a top surface of the pad oxide layer;
depositing a conformal spacer film in the pad nitride layer cavity, wherein the conformal spacer film is deposited along the top surface of the pad oxide layer;
performing a second etch to open the conformal nitride liner and form a trench cavity in the semiconductor substrate;
depositing an oxide layer to fill the trench cavity; and
forming a dummy gate on the trench cavity.

18. The method of claim 17, wherein depositing a conformal nitride liner in the pad nitride layer cavity is performed via a chemical vapor deposition process.

19. The method of claim 17, wherein depositing a conformal nitride liner in the pad nitride layer cavity is performed via a low pressure chemical vapor deposition process.

20. The method of claim 17, wherein forming a trench cavity in the semiconductor substrate comprises forming a trench cavity having a depth ranging from about 80 nanometers to about 110 nanometers, having an upper width ranging from about 28 nanometers to about 32 nanometers, and having a lower width ranging from about 9 nanometers to about 11 nanometers.
